(19) United States
(12) Patent Application Publication
(10) Pub. No.: US 2025/0048537 A1
(43) Pub. Date: Feb. 6, 2025

(54) LOW SWITCHING LOSS INVERTER CIRCUIT BOARD

(71) Applicant: Garrett Transportation I Inc., Torrance, CA (US)

(72) Inventor: Ludek Zavodny, Buchlovice (CZ)

(73) Assignee: Garrett Transportation I Inc., Torrance, CA (US)

(21) Appl. No.: 18/519,143

(22) Filed: Nov. 27, 2023

Related U.S. Application Data
(60) Provisional application No. 63/517,577, filed on Aug. 3, 2023.

(51) Int. Cl. H05K 1/02; H01L 25/16; H02M 1/00; H02M 7/00; H02M 7/537; H05K 1/18

(52) U.S. Cl. CPC H05K 1/0243; H01L 25/16; H02M 1/0054; H02M 7/003; H02M 7/537; H05K 1/0206; H05K 1/0265; H05K 1/18; H05K 2201/10015; H05K 2201/10166

(57) ABSTRACT

A low loss power inverter including a printed circuit board having an upper surface, a lower surface and an internal layer disposed between the lower surface and the upper surface, a first transistor, disposed on the upper surface, having a first terminal, a second transistor, disposed on the upper surface, having a second terminal, and a decoupling capacitor having a first capacitor terminal conductively coupled to the first terminal via a first trace laminated to the upper surface and a second capacitor terminal conductively coupled to the second terminal via a second trace laminated to the lower surface.

### CROSS REFERENCE TO RELATED APPLICATION

The following claims priority to U.S. Provisional Patent Application Ser. No. 63/517,577, filed Aug. 3, 2023, the entire disclosure of which is incorporated by reference.

### TECHNICAL FIELD

The present disclosure generally relates to an electric motor switching inverter and, more particularly, relates to a system for reducing voltage overshoot resulting from parasitic loop inductance in a high speed semiconductor switching application by employing microstrip printed circuit board traces an a top surface and a bottom surface of the printed circuit board.

### BACKGROUND

Rise of electromobility introduces new demands for high power, high efficiency and high power density electrical motor drives. This field is continuously supported by semiconductor component suppliers that bring better and faster active components. For example, the newest generations of silicone or gallium nitride components bring significant potential and as these technologies continue to mature, they are expected to have a major impact on a wide range of industries and applications. These new components are proposing achievement of shorter commutation time and thus lowering switching losses and/or enabling higher switching frequencies. Both these factors are critical to reaching higher power output from a given space or enabling a faster motor spin in the case of electric motors and electric compressors. However, semiconductor components need to be supported by surrounding electronic circuitry to enable utilization of this increased performance.

Parasitic properties of power electronics circuit boards present significant limitation of total system performance in high power electrical motor drives. This is especially true at low voltage systems like those powered from 48V or even 12V network where parasitic loop inductance disables speeding up commutation of low voltage semiconductor components, which can lead to lower efficiency, higher power losses, and reduced performance. Thus, it is desirable to reduce the effects of these parasitic properties to reduce switching loss, increase efficiency and increase performance of power inverter switching circuits to provide a more efficient inverter circuit capable of handing the increased switching speed and performance demands. Other desirable features and characteristics of the present disclosure will become apparent from the subsequent detailed description and the appended claims, taken in conjunction with the accompanying drawings and this background discussion.

### BRIEF SUMMARY

Disclosed herein are fluid compression and motor control methods and systems and related electrical systems for provisioning such systems, methods for making and methods for operating such systems, and motor vehicles and other equipment such as aircraft, ships, wind turbines and other electric vehicles equipped with onboard propulsion systems. By way of example, and not limitation, there are presented various embodiments of systems for providing a low switching loss inverter circuit board having a compact bottom side decoupling path for use in a high power, high efficiency electromobility switching inverter application.

### BRIEF DESCRIPTION OF THE DRAWINGS

The present disclosure will hereinafter be described in conjunction with the following drawing figures, wherein like numerals denote like elements, and wherein:

FIG. 1 illustrates an exemplary inverter arrangement for use in an electric motor application according to exemplary embodiments of the present disclosure;

FIG. 2 shows an exemplary inverter waveform exhibiting undesirable voltage overshoot;

FIG. 3 illustrates an exemplary inverter configuration according to exemplary embodiments of the present disclosure;

FIG. 4 illustrates a cross-sectional view of an exemplary low switching loss inverter PCB configuration according to an exemplary embodiment of the present disclosure;

FIG. 5 illustrates a top view of an exemplary low switching loss inverter PCB configuration according to an exemplary embodiment of the present disclosure; and

FIG. 6 shows another cross-sectional view of an exemplary low switching loss inverter PCB configuration according to an exemplary embodiment of the present disclosure.

### DETAILED DESCRIPTION

The following detailed description is merely exemplary in nature and is not intended to limit the present disclosure or the application and uses of the present disclosure. Furthermore, there is no intention to be bound by any theory presented in the preceding background or the following detailed description.

The rise of electromobility introduces new demands for high power, high efficiency, and high power density electric motor drives. Electric vehicles (EVs) require more powerful motors than traditional internal combustion engine (ICE) vehicles to achieve the same performance as EVs need to accelerate quickly, climb hills, and tow trailers, all while maintaining a long range. In addition, EVs need to be as efficient as possible to maximize their range. This means that the electric motor drive must be highly efficient at converting electrical energy into mechanical energy. Finally, EV powertrains need to be as compact and lightweight as possible to reduce the overall weight of the vehicle and improve its performance.

Electric motors can be used to drive EV powertrains or centrifugal compressors by employing high speed switching of inverter circuitry to supply alternating currents to electric motors. These high speed inverters employ switching transistors that are constantly being improved to increase the switching speeds of the inverters and therefore the rotational speed of the electric motors. These transistors can include insulated gate bipolar transistors (IGBT), metal oxide silicon field effect transistors (MOSFET), or gallium nitride (GaN). Newer power switching components are proposing achievement of shorter commutation time and thus lowering switching loses and/or enabling higher switching frequency. Both above factors are the critical ones to reach higher power output from given space or enabling faster motor spin. However, semiconductor components need to be supported by surrounding electronics circuit that enables utilization of their performance.

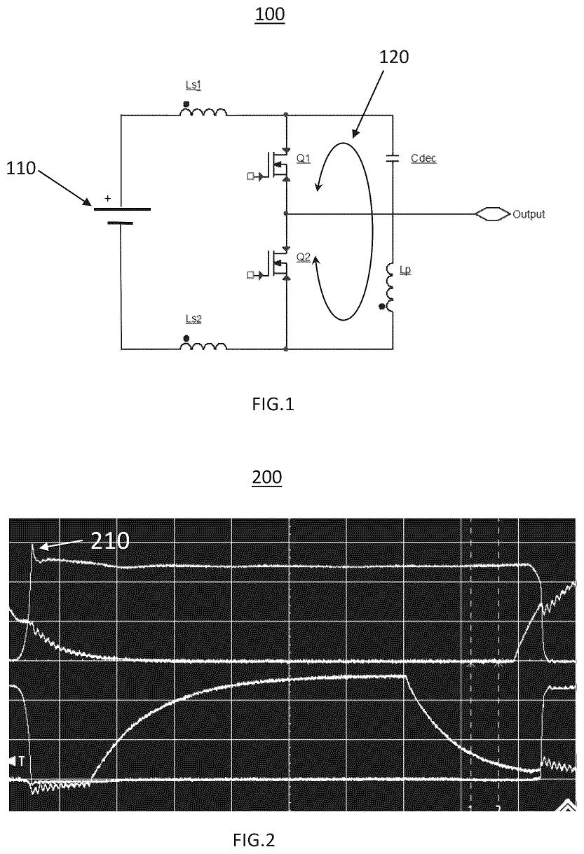

Turning now to FIG. 1, an exemplary inverter arrangement 100 for use in an electric motor application according to exemplary embodiments of the present disclosure is shown. The exemplary inverter arrangement 100 is illustrative of a single phase of a multiphase inverter. The exemplary inverter arrangement includes a DC power source 110, a first transistor Q1, a second transistor Q2 and a decoupling capacitor Cdec. The first transistor Q1 and the second transistor Q2 are arranged in a bridge configuration such that the inverter 100 provides a bipolar alternating signal, with both positive and negative half cycles, to the output. The exemplary inverter arrangement 100 can further include parasitic inductances, such as a first source inductance Ls1, a second source inductance Ls2, and a loop inductance Lp.

Parasitic inductance in a high frequency circuit is the unwanted inductance caused as a result the physical characteristics of the components and the layout of the circuit. It is desirable to limit parasitic inductance as much as possible as it can have a significant impact on the performance of high frequency circuits. Parasitic properties of power electronic circuit boards can present significant limitations of total system performance in high power electrical motor drives, especially in low voltage systems like those powered from 48V or 12V networks where parasitic loop inductance disables speeding up commutation of low voltage semiconductor components.

In exemplary inverter 100, when the first transistor Q1 stops conducting, all the output current from the DC power source 110 is conducted by the second transistor Q2. Ideally, the voltage across the first transistor Q1 rises to the level of the DC power source 110. However, due to the inductances in the circuit Ls1, Ls2, Lp, voltage overshoot can occur on top of the supply voltage for a short time. This overshoot is primarily a result of the parasitic loop inductance Lp on the decoupling capacitor Cdec path. Lowering the parasitic loop inductance Lp on the decoupling capacitor Cdec path can lower the voltage overshoot on the transistor and/or enable faster transistor switching at the same level of voltage overshoot as is shown in FIG. 2.

Turning now to FIG. 2, an exemplary inverter waveform 200 exhibiting undesirable voltage overshoot 210 is shown. The rate of change of current in an inverter is typically very high, so even a small parasitic loop inductance can cause a significant voltage overshoot. The voltage overshoot 210 can result from the parasitic loop inductance Lp and can be a significant portion of the overall signal voltage.

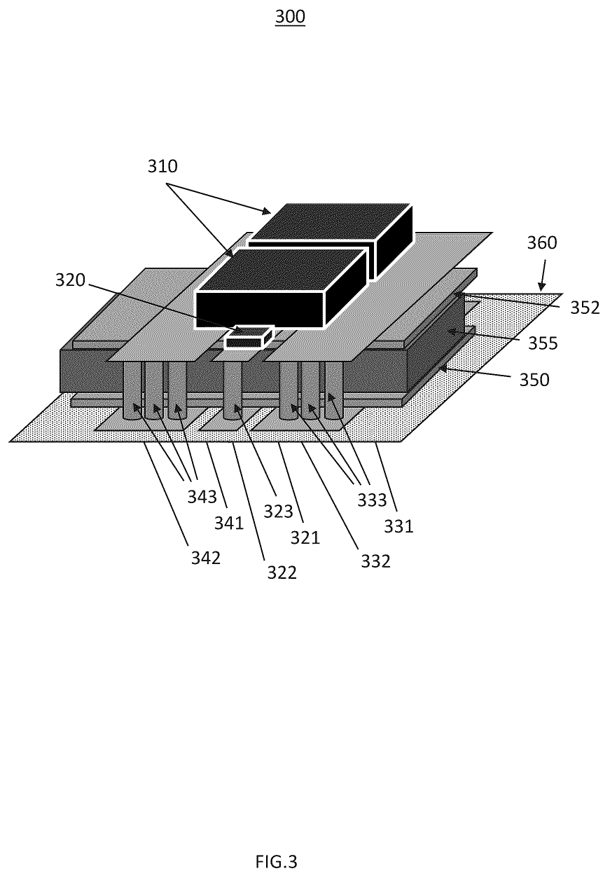

Turning now to FIG. 3, an exemplary inverter configuration 300 according to exemplary embodiments of the present disclosure is shown. The exemplary inverter configuration 300 includes an upper printed circuit board (PCB) surface 352, a lower PCB surface 350 and a thermally conductive inlay 355. The exemplary inverter configuration 200 further includes two switching transistors 310 and a decoupling capacitor 320 mounted to an upper PCB trace 321 and a lower PCB trace 322 electrically coupled by an electrically conductive via 323. The upper PCB trace 321, a lower PCB trace 322, electrically conductive via 323 and a second electrically conductive via (not shown) are configured to provide a decoupling path between a first voltage source and a second voltage source. Additionally, PCB traces 331, 332, 341, 342 and corresponding thermally conductive vias 333, 343 are configured to provide thermal transfer between the switching transistors 310 and the thermally conductive inlay 355. The lower PCB surface 350, the upper PCB surface 352 and the thermally conductive layer 355 are depicted as having reduced horizontal dimensions in FIG. 3 for clarity. These surfaces can extend further in the horizontal directions as required and should encompass the thermally conductive vias 333, 343 and the electrically conductive via 323.

The thermally conductive inlay 355 can be used to transfer heat away from the switching transistors 310 to a cold plate 360. Thermally conductive traces 331, 341 on the upper surface of the upper PCB surface 352 conduct heat away from the switching transistors 310 and couple this heat to the thermally conductive layer 355 through the thermally conductive vias 333, 343. In addition, the thermally conductive vias 333, 334, or additional thermally conductive vias travelling through the lower PCB surface 350 can further conduct heat from the thermally conductive layer 355 to PCB traces 332, 342 on the lower PCB surface 350 In some exemplary embodiments, the cold plate 360 can be a metal plate that is used to transfer heat from electronic components to a liquid coolant, such as ambient air or water. The cold plate 360 can be used to keep the transistors 310 cool to prevent them from overheating.

To address the problem of excessive loop inductance in the decoupling capacitor signal path, it is desirable to increase the PCB trace width to lower inductance and to reduce the loop area as much as possible. In addition, introducing a thermally conductive material within the loop, such as ferrite, can further reduce the loop inductance. The proposed system routes the decoupling path underneath the transistors with the thermally conductive inlay 355 within the loop. In some exemplary embodiments, the upper PCB trace 321 and a lower PCB trace 322 can each be 3 mm wide and 30 mm long to decouple one phase leg of the inverter. The lamination thickness of the PCB traces 321, 322 can be 0.1 mm resulting in a microstrip on PCB trace with very low inductance. As the PCB traces 321, 322 are significantly wider than the lamination thickness a microstrip is formed having a very low inductance, significantly decreasing the decoupling path inductance compared to that of a decoupling path printed on a single side of a PCB.

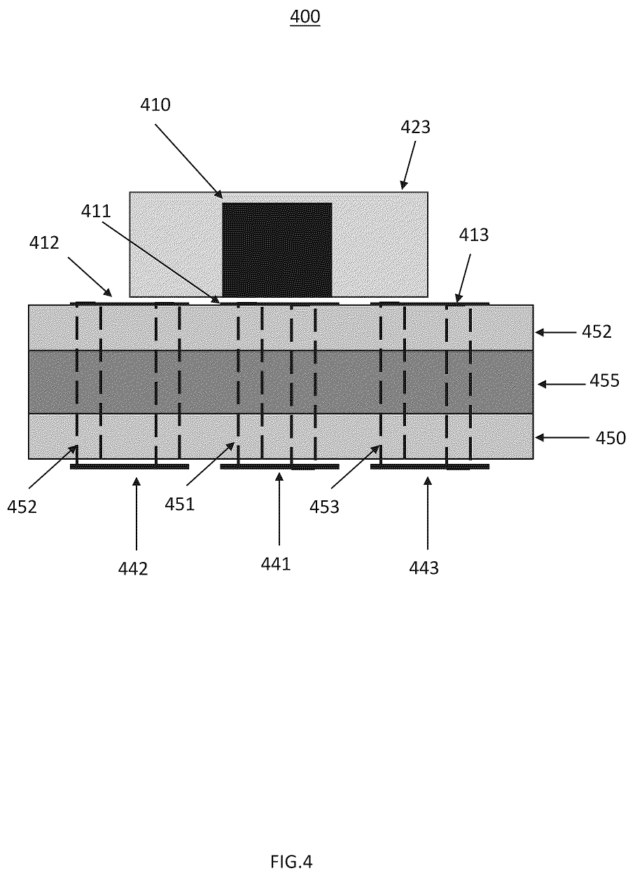

Turning now to FIG. 4, a cross-sectional view of an exemplary low switching loss inverter PCB configuration 400 according to an exemplary embodiment of the present disclosure is shown. The exemplary PCB configuration 400 is illustrative of a cross-sectional view taken orthogonally from the plane of the decoupling path loop. The PCB configuration 400 includes an upper PCB surface 452, a lower PCB surface 450 and a thermally conductive layer 455. The decoupling path runs from a source pin of a first transistor 423, and includes the decoupling capacitor 410, an upper decoupling PCB trace 411, a first plurality of vias 451 at a first end of a lower decoupling PCB trace 441, the lower decoupling PCB trace 441 laminated on the lower PCB surface 450, a second plurality of vias (not shown) at a second end of the lower decoupling PCB trace 411, to a portion the upper decoupling PCB trace 411 laminated on the upper PCB surface 452, to a source pin of a second switching transistor (not shown). In some exemplary embodiments, the thermally conductive layer 455 is thermally coupled to a first cooling surface 412 and a second cooling surface 413 laminated on the upper PCB surface by thermally conductive vias 452, 453. In some exemplary embodiments, these thermally conductive vias 452, 453 can conduct heat to a first heat transfer surface 442 and a second heat transfer surface 443. These heat transfer surfaces 442, 443 can be laminated to the lower PCB surface 452 and can couple heat to ambient air, a cold plate, or the like.

The loop inductance experienced by the decoupling loop can be minimized by increasing the width to the upper decoupling PCB trace 411, and the lower decoupling PCB trace 441 to create a microstrip structure. Furthermore, positioning the first plurality of vias 451 and the second plurality of vias to reduce the area of the decoupling loop can further help to reduce the loop area resulting in a reduced loop inductance. In some exemplary embodiments, positioning vias such that a plurality of loop areas are formed can reduce a severity of any overshoot created by distributing the overshoot over time due to the different propagation times through the various decoupling loops. In some exemplary embodiments, selecting a material, such as ferrite, for the thermally conductive layer 455 to provide impedance to the decoupling loop currents while still providing sufficient thermal conduction can further reduce the overshoot experienced due to decoupling loop inductance.

Turning now to FIG. 5, a top view of an exemplary low switching loss inverter PCB configuration 500 according to an exemplary embodiment of the present disclosure is shown. The top view is illustrative of the PCB 510, the decoupling capacitor 515, the first transistor 520, the second transistor 525 mounted to the top side of the PCB 510 and the decoupling loop PCB trace 530 laminated to a bottom side of the PCB 510. The decoupling loop PCT trace 530 can be electrically coupled by vias to top side laminated pads (not shown) under the decoupling capacitor 515 and the second transistor 525 to complete the decoupling loop between a source pin of the first transistor 520, the decoupling capacitor 515 and a source pin of the second transistor 525.

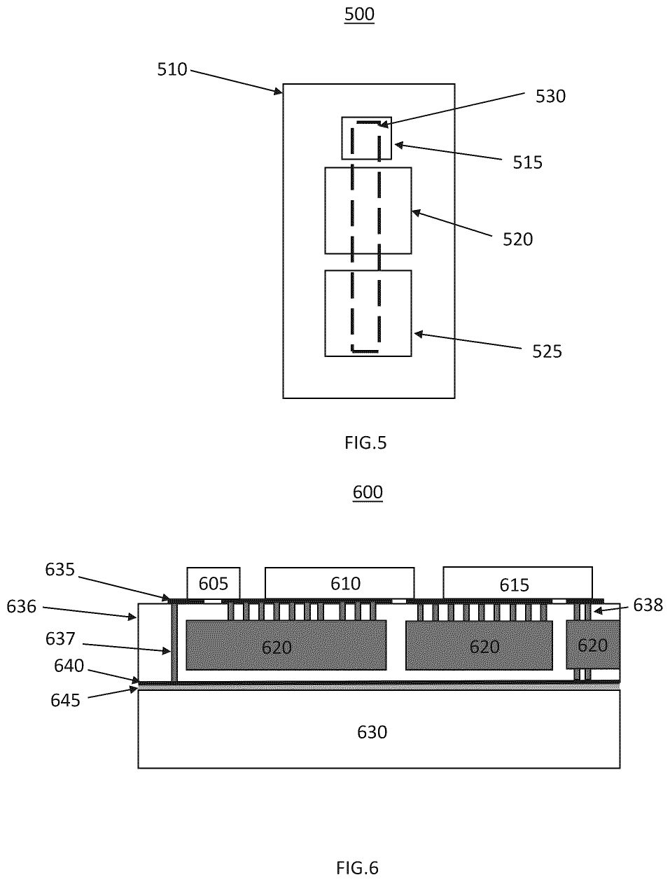

Turning now to FIG. 6, another cross-sectional view of an exemplary low switching loss inverter PCB configuration 600 according to an exemplary embodiment of the present disclosure is shown. The exemplary PCB configuration 600 is illustrative of a cross-sectional view taken parallel to the plane of the decoupling path loop. The PCB configuration 600 includes a decoupling capacitor 605, a first transistor 610, a second transistor 615, non conductive laminate 636, thermally conductive inlay 620, thermal interface material 645, an upper PCB trace 635, a lower PCB trace 640, a first via 637, a second via 638, and a cold plate 630.

The decoupling loop signal path is shown running from a source pin of the first transistor 610, through the upper PCB trace 635 through the decoupling capacitor 605, through a second portion of the upper PCB trace 635, the first via 637 to the lower PCB trace 640, the second via 638 to a third portion of the upper PCB trace 635 to a source pin of the second transistor 615. In some exemplary embodiments, the decoupling loop provides a conductive decoupling path around at least two portions of the thermally conductive inlay 620. The thermally conductive inlay 620 can be thermally coupled to the cold plate via additional vias to thermally conducted surfaces laminated on a lower surface of the PCB and the thermal interface material 645.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the present disclosure in any way. Rather, the foregoing detailed description will provide those skilled in the art with a convenient road map for implementing an exemplary embodiment of the present disclosure. It is understood that various changes may be made in the function and arrangement of elements described in an exemplary embodiment without departing from the scope of the present disclosure as set forth in the appended claims.

What is claimed is:

1. An inverter comprising:
a printed circuit board having an upper surface, a lower surface and an internal layer disposed between the lower surface and the upper surface;
a first transistor, disposed on the upper surface, having a first terminal and a first drain terminal;
a second transistor, disposed on the upper surface, having a second terminal and a second drain terminal; and
a decoupling capacitor having a first capacitor terminal conductively coupled to the first drain terminal via a first trace laminated to the upper surface and a second capacitor terminal conductively coupled to the second terminal via a second trace laminated to the lower surface and the first terminal being conductively coupled to the second drain terminal via a third trace laminated to the upper surface.

2. The inverter of claim 1 wherein the second trace is conductively coupled to the first capacitor terminal via a first via and the second terminal is conductively coupled to the second trace via a second via.

3. The inverter of claim 2 wherein the first trace, the first via, the second trace, the third trace and the second via form a signal loop orthogonal to a plane of the printed circuit board.

4. The inverter of claim 1 further wherein the internal layer is a thermally conductive layer thermally coupled to the first transistor and the second transistor and wherein the thermally conductive layer is electrically isolated from the first trace and the second trace.

5. The inverter of claim 1 wherein the first trace has a thickness of less than 0.11 mm and a width greater than 3 mm.

6. The inverter of claim 1 wherein the second trace and the third trace have a width to thickness ratio of at least 30:1.

7. The inverter of claim 1 wherein the first terminal is a first source terminal, and the second terminal is a second source terminal.

8. The inverter of claim 1 wherein the first transistor further includes a first drain terminal and the second transistor includes a second drain terminal and wherein the first terminal and the second drain terminal are electrically coupled to a motor winding.

9. The inverter of claim 1 wherein the first transistor is a high side transistor and the second transistor is a low side transistor.

10. A method comprising:
disposing a first transistor on an upper surface of a printed circuit board, the first transistor having a first terminal;
disposing a second transistor on the upper surface of the printed circuit board, the second transistor having a second terminal; and
disposing a decoupling capacitor on the upper surface of the printed circuit board, the decoupling capacitor having a first capacitor terminal conductively coupled to the first terminal via a first trace laminated to the upper surface and a second capacitor terminal conductively coupled to the second terminal via a second trace laminated to a lower surface of the printed circuit board.

11. The method of claim 10 further including a thermally conductive layer thermally coupled to the first transistor and the second transistor and disposed between the lower surface and the upper surface.

12. The method of claim 11 wherein the thermally conductive layer is electrically isolated from the first trace and the second trace.

13. The method of claim 10 wherein the first trace laminated to the upper surface and the second trace laminated to the lower surface of the printed circuit board are electrically coupled using a plurality of vias.

14. The method of claim 10 wherein the first trace laminated to the upper surface and the second trace laminated to the lower surface of the printed circuit board are electrically coupled using a plurality of micro vias.

15. The method of claim 10 wherein the second capacitor terminal is conductively coupled to the second trace using a plurality of conductive vias.

16. The method of claim 10 wherein the first drain terminal is electrically coupled to a first voltage source terminal and the second terminal is a second source terminal electrically coupled to a second voltage source terminal.

17. The method of claim 10 wherein the printed circuit board further includes a ferrite layer disposed between the upper surface and the lower surface and wherein the ferrite layer is electrically isolated from the first trace and the second trace.

18. The method of claim 10 wherein the second trace is a microstrip trace having a width greater than 3 millimeters and a thickness less than 0.2 millimeters.

19. A power inverter comprising:
a source of a fixed voltage having a positive terminal and a negative terminal;
a printed circuit board having an upper layer, a lower layer and an internal layer wherein the upper layer and the lower layer are non-conductive and the internal layer is thermally conductive;
a first transistor disposed on the upper layer having a first drain terminal electrically coupled to the positive terminal;
a second transistor disposed on the upper layer having a second terminal electrically coupled to the negative terminal; and
a decoupling capacitor disposed on the upper layer having a first capacitor terminal conductively coupled to the first drain terminal via a first trace laminated to an upper surface of the upper layer and a second capacitor terminal conductively coupled to the second terminal via a second trace laminated to a lower surface of the lower layer and wherein the first trace is conductively coupled to the second trace by a plurality of conductive vias passing through the internal layer.

20. The power inverter of claim 19 wherein the internal layer is a thermally conductive layer thermally coupled to a cooling plate via a plurality of thermally conductive surfaces laminated to the lower layer and wherein the decoupling capacitor, upper PCB trace and lower PCB trace are electrically isolated from the thermally conductive layer.
